(19) United States
(12) Patent Application Publication
(10) Pub. No.: US 2012/0056661 A1
(43) Pub. Date: Mar. 8, 2012

(54) HIGH VOLTAGE MULTIPLEXER ELEMENT AND MULTIPLEXER SYSTEM USING SAME

(76) Inventor: Ayman Shabra, Woburn, MA (US)

(21) Appl. No.: 12/877,111

(22) Filed: Sep. 8, 2010

(51) Int. Cl. H03K 17/687

(52) U.S. Cl. 327/436

(57) ABSTRACT

This invention features a high voltage multiplexer element including a voltage to current converting input resistance connected to the input of the element, first and second MOSFET switches connected in series between the input resistance and the output of the multiplexer element, and a third MOS switch connected between the junction of the first and second MOSFET switches and a voltage equal to or less than the supply; the first MOSFET switch being drain engineered and having drain-source breakdown voltage higher than the supply.

### FIELD OF THE INVENTION

This invention relates to an improved high voltage multiplexer element and to multiplexer system made therewith, and has a particular application in analog to digital converter (ADC) applications.

### BACKGROUND OF THE INVENTION

An analog to digital converter (ADC) may be shared between multiple measurement channels using a voltage multiplexer. The multiplexer allows for any individual input channel to be connected to the ADC, while at the same time disconnecting other channels. This provides for an economic solution for the measurement problem when concurrent measurements are not needed. This saves area on the integrated circuit device by avoiding the need for a dedicated ADC for each measurement channel. The voltage multiplexer is a simple circuit composed of switches implemented using transistors and is generally much smaller in area compared to the ADC.

In many applications it is desirable to measure voltages which are higher than the voltage allowed for reliable operation of the transistor switches in a given silicon processing technology. If the input voltage to the multiplexer is higher than the voltage allowed for a reliable transistor, then the transistor will either breakdown or exhibit a reduced mean time to failure. One way to address this problem is to attenuate the input voltage before it is applied to the multiplexer, using a voltage divider. The combination of resistors can be designed to force the voltage to be within the tolerable voltage range of the transistors. In addition to the extra components needed, the disadvantage of this approach is high noise and reduced measurement accuracy due to the component tolerances of the voltage divider resistors. Another potential disadvantage of this approach is the static current drawn by the voltage divider resistors.

### SUMMARY OF THE INVENTION

In accordance with various aspects of the subject invention in at least one embodiment the invention presents an improved high voltage multiplexer element which is simpler, less expensive and requires less space, which eliminates the need for a voltage reducing voltage divider and which is more accurate and has better signal to noise characteristics.

The subject invention results from the realization that, in part, an improved smaller, more accurate and less noisy high voltage multiplexer element in various aspects can be achieved by using first and second MOSFET switches connected in series between the input resistance and the output of the multiplexer element and a third MOSFET switch connected between the junction of the first and second MOSFET switches and a supply voltage; the first MOSFET switch is drain engineered and has drain source breakdown voltage higher than the supply.

The subject invention, however, in other embodiments, need not achieve all these objectives and the claims hereof should not be limited to structures or methods capable of achieving these objectives.

This invention features a high voltage multiplexer element including a voltage to current converting input resistance connected to the input of the element, first and second MOSFET switches connected in series between the input resistance and the output of the multiplexer element, and a third MOS switch connected between the junction of the first and second MOSFET switches and a voltage equal to or less than the supply; the first MOSFET switch being drain engineered and having drain-source breakdown voltage higher than the supply.

In a preferred embodiment the first and second MOSFET switches may be NMOS switches and the third MOSFET switch may be a PMOS switch. The first and second MOSFET switches may be PMOS switches and the third MOSFET switch may be an NMOS switch.

This invention also features a high voltage multiplexer system including a plurality of multiplexer elements including a voltage to current converting input resistance connected to the input of each the element, first and second MOSFET switches connected in series between the input resistance and the output of each multiplexer element, and a third MOS switch connected between the junction of the first and second MOSFET switches and a voltage equal to or less than the supply; the first MOSFET switch being drain engineered and having drain-source breakdown voltage higher than the supply.

In preferred embodiment the first and second MOSFET switches may be NMOS switches and the third MOSFET switch may be a PMOS switch. The first and second MOSFET switches may be PMOS switches and the third MOSFET switch may be an NMOS switch.

This invention also features a high voltage multiplexer system for an analog to digital converter including an integrator having an input resistance and an operational amplifier, loop filter, quantizer and a feedback digital to analog converter. The multiplexer system includes a plurality of multiplexer elements each including first and second MOSFET switches connected in series between the input resistance and the operational amplifier, and a third MOS switch connected between the junction of the first and second MOSFET switches and a voltage equal to or less than the supply; the first MOSFET switch being drain engineered and having drain-source breakdown voltage higher than the supply.

In a preferred embodiment the first and second MOSFET switches may be NMOS switches and the third MOSFET switch may be a PMOS switch. The first and second MOSFET switches may be PMOS switches and the third MOSFET switch may be an NMOS switch.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a simplified schematic diagram of conventional prior art multiplexer system;

FIG. 2 is a more detailed view of the prior art multiplexer system of FIG. 1 implemented with MOSFET switches;

FIG. 3 is a schematic diagram of a conventional prior art multiplexer system using a voltage divider to keep the voltage within reliability range;

FIG. 4 is a schematic diagram of a multiplexer element in accordance with one embodiment of this invention;

FIG. 5 is a schematic diagram of a continuous time ΔΣ ADC (CT ΔΣ ADC) employing a multiplexer system and elements according to one embodiment of this invention;

FIG. 6 is a schematic diagram of a CT ΔΣ ADC employing a multiplexer system in accordance with one embodiment of the invention used with a conventional multiplexer system; and

FIG. 7 is a schematic diagram of a CT ΔΣ ADC employing a multiplexer system in accordance with one embodiment of the invention used in a differential configuration.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

The invention disclosed herein allows for the measurement of high voltages without compromising the reliability of the multiplexer semiconductor (transistor) switches and without using a voltage divider with its attendant accuracy and noise problems. It also avoids a need for dedicated ADC's for each high voltage channel and thereby provides for an area efficient solution.

There is shown in FIG. 1 a traditional implementation of a voltage multiplexer 10 including three switches 12, 14 and 16. The output of multiplex 10 is delivered at point 18 to analog to digital converter (ADC) 20. At its input multiplexer 10 receives input signals V1, V2, and V3 at switches 12, 14 and 16. When a particular switch receives the signal ON1, ON2, ON3, respectively, it will close delivering its input V1, V2, or V3 to input/summing point 18 of ADC 20. A multiplexer has a large number of such switches but only three are shown here for simplicity of illustration. Switches 12, 14 and 16 may be implemented with MOSFET switches of the NMOS, CMOS or PMOS type.

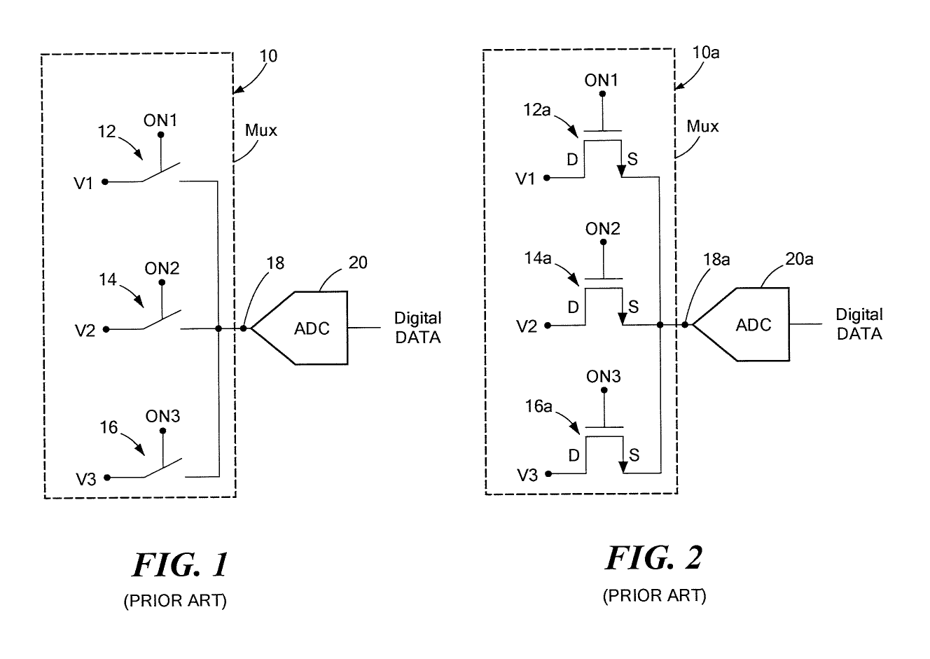

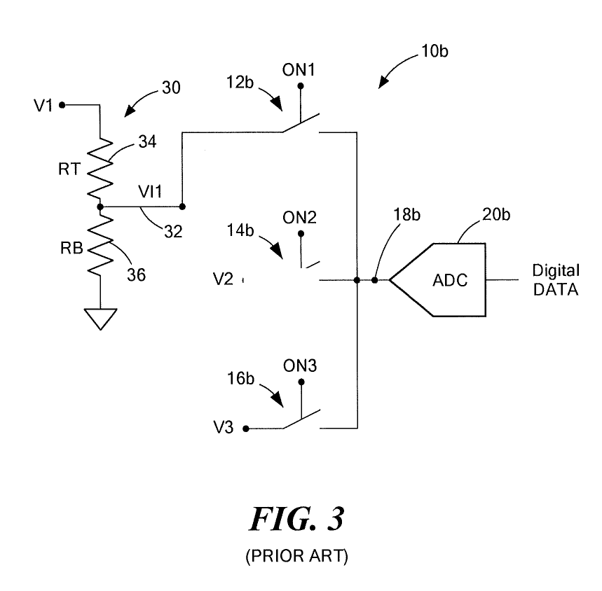

In FIG. 2, the switches are implemented by NMOS switches 12a, 14a, and 16a. One prior art uses a voltage divider 30, FIG. 3, to attempt to generate a voltage VI1 on line 32 which is within the allowed reliability range of switches 12b, 14b, and 16b. Voltage divider 30 includes two voltage divider resistors RT 34 and RB 36. This approach attenuates the input voltage before it is applied to the multiplexer by subjecting it to voltage divider 30 where the combination of resistors 34 and 36 is designed to force the voltage at 32 to be within the tolerable range of the switches 12b, 14b, 16b. This approach suffers from reduced accuracy due to the accuracy limits of the resistors 34 and 36 and also introduces additional noise.

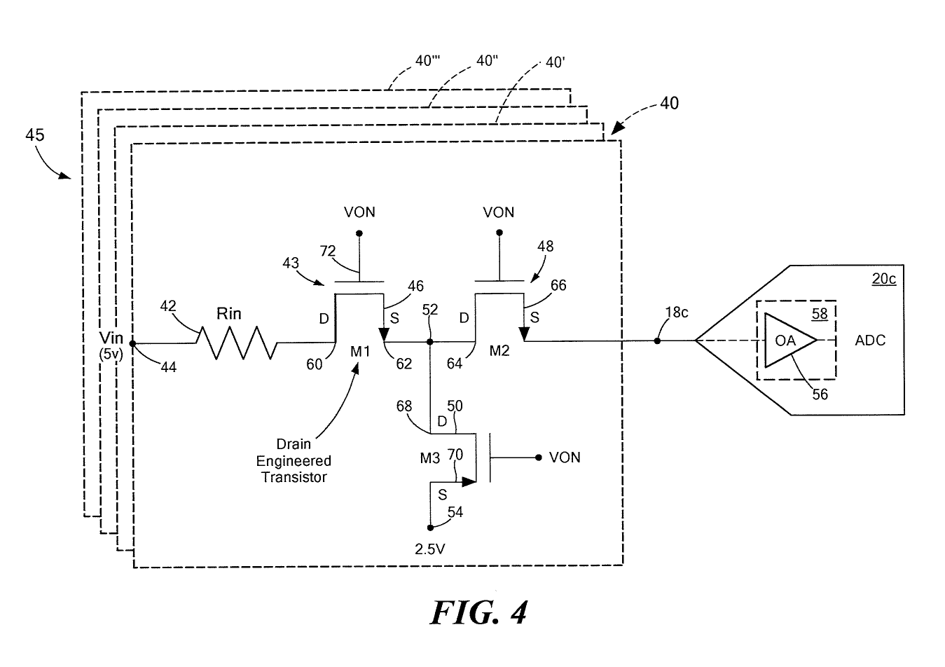

In accordance with one embodiment of this invention high voltage multiplexer element 40, FIG. 4 includes a voltage to current converting input resistance Rᵢₙ 42, which is connected to the input 44 of multiplexer element 40. The multiplexer system 45 according to one embodiment of the invention is formed of a number of multiplexer elements 40, 40′, 40″, 40′″ also according to the invention only one of which, multiplexer 40, is explained here as representative. In addition to Rᵢₙ resistance 42 each multiplexer element 40 includes a switching circuit 43 including MOSFET switch 46, 48 and 50. MOSFET switches 46 and 48 are connected in series between input resistance Rᵢₙ 42 and the output at summing junction 18c at the input of opamp 56 of integrator 58 of ADC 20c. A third MOSFET switch 50 is connected between the junction or node 52 of MOSFET switches 46 and 48 and supply voltage 54. The circuit of multiplexer element 40 has two possible states: either multiplexer element 40 is enabled, in which case Vᵢₙ is connected to output or summing point 18c or multiplexer element 40 is disabled and voltage Vᵢₙ at input 44 is not connected to output or summing point 18c. MOSFET switches 46, 48 are shown as NMOS switches in FIG. 4 and MOSFET switch 50 as PMOS switch. The polarities of these switches could be reversed in which case the control voltages would be inverted as well. When multiplexer element 40 is enabled the voltage Vₒₙ is equal to the supply voltage (2.5V in this particular example) which appears at 54. Node 54 is preferably connected to the supply voltage, but may also be connected to any voltage less than or equal to the supply voltage. This causes transistors 46 and 48 to conduct while transistor 50 becomes an open circuit. The voltage seen by the drain 60 and source 62 of switch 46 and drain 64 and source 66 of switch 48 is the output voltage which if the multiplexer element is used in conjunction with an ADC is actually the summing point or junction 18c of the integrator 58 operational amplifier 56 of the ADC 20c: the voltage seen by the drain and source terminals 60-66 is the voltage on summing point or junction 18c of the operational amplifier 56 of the integrator 58 of the ADC 20c. This voltage value can be designed to fall safely within the tolerable operating voltage range of the switches. In this particular example the summing point or junction voltage is 1.2V. The drain 68 of switch 50 is also at the voltage of the summing junction 18c while the source voltage is connected to the supply voltage of 2.5V at 54. When the multiplexer element 40 is disabled the voltage Vₒₙ is equal to 0. This forces switches 46 and 48 into an open circuit while switch 50 conducts. This results in the following voltage conditions. The drain 60 of switch 46 is equal to Vᵢₙ and the source 62 of switch 46 is equal to the supply voltage 2.5V. The drain 64 of switch 48 is equal to the supply voltage 2.5V. The source 66 of switch 48 is equal to the voltage at summing junction 18c. The drain 68 of switch 50 is equal to the supply voltage 2.5V as is the source of switch 50. Thus, the only semiconductor device which may experience a high voltage under this configuration is switch 46 because the drain terminal 60 is connected to Vᵢₙ at input 44. This voltage could rise to as high as 5V but in accordance with this invention transistor 46 is a drain engineered MOSFET, for further explanation of drain engineered transistors see “Cellular Handset Integration—SIP Versus SOC” by William Krenik et al., Journal of Solid State Circuits, page 1842, Vol. 40, No. 9, September 2005. This allows switch 46 to withstand a higher voltage. Note that the gate 72 to source 62 junction of switch 46 cannot withstand high voltages and the circuit configuration sets this voltage as always within the acceptable limits under all operating conditions. While in the particular case explained here the normal junction safe voltage is 2.5V and the drain engineered switch 46 has an increased safe voltage of 5V, this is not a limitation of the invention. The breakdown voltages are not fixed at 2.5V normally and 5V for the drain engineered switch as used in this example but rather depend upon need and can be varied in accordance with foundry processes. The multiplexer element of this invention then provides the multiplexer function across higher voltage inputs without the need for a voltage divider and its attendant added inaccuracies and noise. When switch 50 is on or conducting multiplexer element 40 is off and in that condition serves to keep summing junction 18c at a fixed voltage, namely the supply voltage in this particular case, 2.5V. Switch 48 functions to provide isolation from the summing junction 18c when switch 50 is conducting.

One useful application of the multiplexer elements and system according to this invention is with a continuous-time ΔΣ ADC (CT ΔΣ ADC) or any other operational amplifier based continuous-time circuit which has an input structure composed of a resistor connected to the operational amplifier summing junction, such as linear filters, companding circuits, log amplifiers, signal conditioner circuits amongst others.

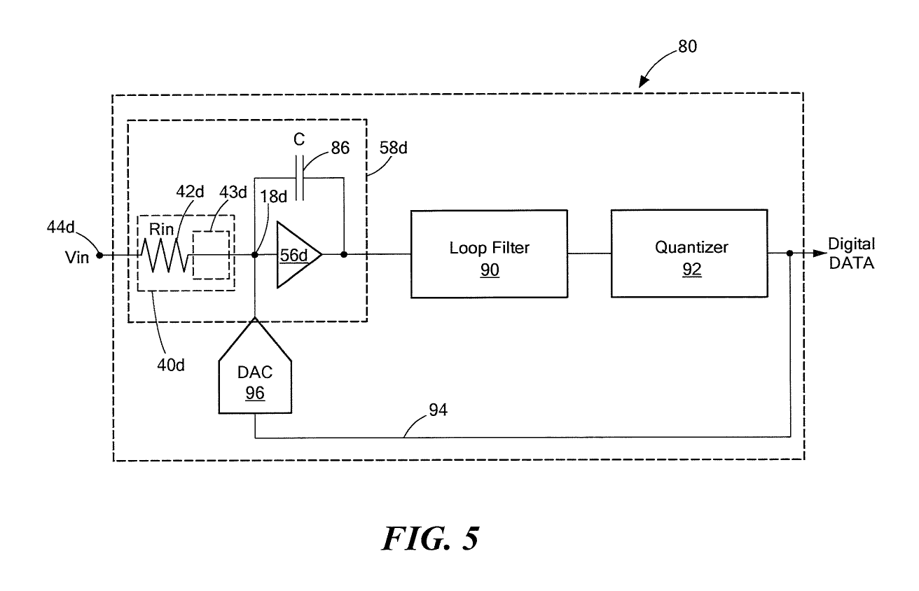

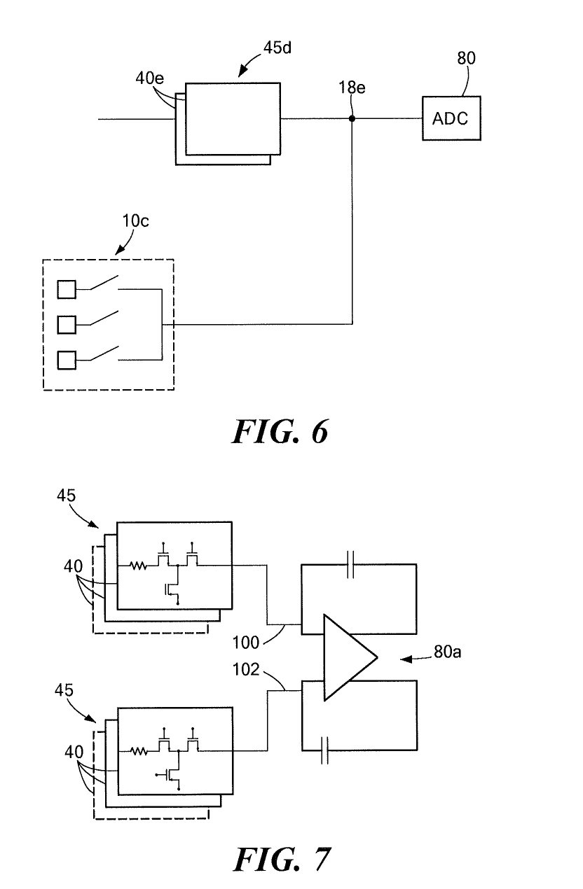

A typical continuous-time ΔΣ ADC 80 is shown in FIG. 5. It contains an integrator circuit 58d including an input resistance 42d, capacitor 86 and operational amplifier 56d. Integrator circuit 58d is connected directly between Vᵢₙ 44a and loop filter 90. CT ΔΣ ADC also includes a quantizer 92 and a feedback loop 94 including feedback digital to analog converter 96 whose output is connected to summing junction 18d. Here multiplexer element 40d is employed using its switching circuit 43d in conjunction with input resistance 42d which is actually the input resistance to operational amplifier 56d. The resistance has to be replicated for each input so 40d is the same as 40′ in FIG. 4; 43d would be transistors 46, 48, and 50 in FIG. 4; and resistor 42d will be the same as resistor 42 in FIG. 4. Multiplexer system 45e, FIG. 6, may be the sole multiplexer connected to summing junction 18e of CT ΔΣ ADC 80, FIG. 6, or it may be used in conjunction with a conventional multiplexer 10c.

While multiplexer elements 40 and multiplexer system 45 using them are shown in single ended configuration, this is not a necessary limitation of the invention, for as shown in FIG. 7 ADC 80a may have a multiplexer system 45 connected to each of its differential inputs 100 and 102.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. A high voltage multiplexer element comprising:
a voltage to current converting input resistance connected to the input of said element;
first and second MOSFET switches connected in series between said input resistance and the output of said multiplexer element; and
a third MOS switch connected between the junction of said first and second MOSFET switches and a voltage equal to or less than the supply; said first MOSFET switch being drain engineered and having drain-source breakdown voltage higher than the supply.

2. The high voltage multiplexer element of claim 1 in which said first and second MOSFET switches are NMOS switches and said third MOSFET switch is a PMOS switch.

3. The high voltage multiplexer element of claim 1 in which said first and second MOSFET switches are PMOS switches and said third MOSFET switch is an NMOS switch.

4. A high voltage multiplexer system including a plurality of multiplexer elements comprising:
a voltage to current converting input resistance connected to the input of each said element;
first and second MOSFET switches connected in series between said input resistance and the output of each said multiplexer element; and
a third MOS switch connected between the junction of said first and second MOSFET switches and a voltage equal to or less than the supply; said first MOSFET switch being drain engineered and having drain-source breakdown voltage higher than the supply.

5. The high voltage multiplexer element of claim 4 in which said first and second MOSFET switches are NMOS switches and said third MOSFET switch is a PMOS switch.

6. The high voltage multiplexer element of claim 4 in which said first and second MOSFET switches are PMOS switches and said third MOSFET switch is an NMOS switch.

7. A high voltage multiplexer system for an analog to digital converter including an integrator having an input resistance and an operational amplifier, loop filter, quantizer and a feedback digital to analog converter, said multiplexer system including a plurality of multiplexer elements each comprising:
first and second MOSFET switches connected in series between said input resistance and said operational amplifier; and
a third MOS switch connected between the junction of said first and second MOSFET switches and a voltage equal to or less than the supply; said first MOSFET switch being drain engineered and having drain-source breakdown voltage higher than the supply.

8. The high voltage multiplexer system of claim 7 in which said first and second MOSFET switches are NMOS switches and said third MOSFET switch is a PMOS switch.

9. The high voltage multiplexer element of claim 7 in which said first and second MOSFET switches are PMOS switches and said third MOSFET switch is an NMOS switch.
